(19) United States
(12) Patent Application Publication
(10) Pub. No.: US 2025/0362526 A1
(43) Pub. Date: Nov. 27, 2025

(54) FOLDABLE AERIAL IMAGE DISPLAY DEVICE

(71) Applicant: INTERMAN Corporation, Kagoshima (JP)

(72) Inventor: Shigeki UETABIRA, Kagoshima (JP)

(73) Assignee: INTERMAN Corporation, Kagoshima (JP)

(21) Appl. No.: 18/867,935

(22) PCT Filed: May 4, 2023
(86) PCT No.: PCT/JP2023/017213

§ 371 Date: Nov. 21, 2024

(30) Foreign Application Priority Data
Jun. 7, 2022 (JP) 2022-092231

(51) Int. Cl. G02B 30/56

(52) U.S. Cl. CPC G02B 30/56

(57) ABSTRACT

An aerial image display device is provided which can be folded into a small size and freely carried. The aerial image display device includes a display substrate displaying a contactless interface, an optical plate connected to the display substrate by a hinge member, and a support structure capable of fixing the display substrate and the optical plate at a predetermined angle. When the contactless interface is displayed on the display substrate with the display substrate and the optical plate being fixed at the predetermined angle, the contactless interface is displayed as an aerial image via the optical plate in air on the opposite side of the optical plate. The display substrate, the optical plate and the support structure can be stacked on each other and folded into a plane.

### TECHNICAL FIELD

The present invention relates to a compact foldable aerial image display device capable of displaying an aerial image.

### BACKGROUND TECHNOLOGY

The new coronavirus has occurred a pandemic and let people know how the densely populated, high-speed and volume transportation society in the 21st century is vulnerable to an infectious disease. In such a situation, everything around us looks an infectious agent so that daily life becomes confining. In fact, it seems necessarily to doubt everything in an infection spread situation.

While it is important to take measures such as wearing a mask, keeping sufficient distances from others, avoiding all crowded spaces, it is inevitable to make minimum contact with an infection route for carrying out life in society. To minimize this risk as small as possible is vital for preventing infection.

For example, in the case of bank ATMs, supermarket self-checkout machines, corporate reception desks, hotel check-ins, etc., an unspecified number of users are required to operate the same touch panel. Such touch panels can be a potential route of infection. In order to avoid this risk, it is necessary to disinfect the touch panel every time the user changes, but such a procedure is rather time-consuming and difficult to carry out satisfactorily.

In recent years, in such a situation, attention has been focused on a technology capable of contactless manipulation using an aerial image formed in the air with a special optical element. By using this technology, it is possible to realize a completely contactless interface with the same usability as a conventional touch panel.

For example, in Patent Document 1, a contactless remote pointer control device with an aerial imaging technology is used to operate a mouse displayed on the device. This is because it is considered unhygienic for a surgeon to touch pointing devices such as a computer mouse during surgery. As such a special optical element, for example, there is an optical imaging device described in Patent Document 2.

### PRIOR ART LITERATURE

### Patent Document

Japanese Unexamined Patent Application Publication No. 2018-147054 International Publication No. 2009/131128

### SUMMARY OF INVENTION

### Problems to be Solved by the Invention

The current aerial image display devices, however, are of the stationary type, which means they are basically designed to be installed in a specific location and not to be moved afterwards. For example, it is not possible to perform contactless online payments by carrying it in a bag and visiting a destination.

Taking into consideration the above circumstances, it is an object of the present invention therefore to provide a foldable aerial image display device which can be folded into a small size and freely carried.

### Means to Solve the Problems

In order to solve the above problems, an aerial image display device according to one aspect of the present invention comprises a display substrate that displays a contactless interface; an optical plate connected to the display substrate by a hinge member; and a support structure capable of fixing the display substrate and the optical plate at a predetermined angle; wherein when the contactless interface is displayed on the display substrate with the display substrate and the optical plate being fixed at the predetermined angle, the contactless interface is displayed as an aerial image via the optical plate in air on the opposite side of the optical plate, and wherein the display substrate, the optical plate and the support structure can be stacked on each other and folded into a plane.

In one embodiment, the support structure comprises a support substrate connected with the display substrate by a hinge member, and the support substrate can be folded flat together with the display substrate and the optical plate.

Furthermore, in one embodiment, the support substrate incorporates an information processing apparatus for transmitting a control signal for displaying the contactless interface on the display substrate.

Furthermore, in one embodiment, the support structure further includes a locking means for engaging the display substrate, the optical plate and the support substrate and fixing the display substrate, the optical plate and the support substrate at a predetermined angle.

Further, in one embodiment, the optical plate and the support substrate are horizontally held by the support structure, and the angles between the display substrate, and the optical plate and the support substrate are in the range of 40 degrees to 50 degrees.

### Effects of the Invention

In accordance with the foldable aerial image display device of the present invention, it can be folded small and carried freely, and a development environment using actual equipment can be set up on the spot, allowing easy modification and addition of implementation.

### BRIEF DESCRIPTION OF DRAWINGS

FIG. 1 is a diagram showing an aerial image display device 1 in use in accordance with an embodiment 1 of the present invention.

FIG. 2 is a side view showing the aerial image display device 1 in use in accordance with the embodiment 1 of the present invention.

FIG. 3 is a side view of the folded state of the aerial image display device 1 in accordance with the embodiment 1 of the present invention.

FIG. 4 is a front view of the folded state of the aerial image display device 1 in accordance with the embodiment 1 of the present invention.

FIG. 5 is a back view showing the folded state of the aerial image display device 1 in accordance with the embodiment of the present invention.

FIG. 6 is a diagram showing a blackout curtain used for the aerial image display device 1 in accordance with the embodiment 1 of the present invention.

FIG. 7 is a diagram showing the blackout curtain of FIG. 6 attached to the aerial image display device 1 in accordance with the embodiment 1 of the present invention.

FIG. 8 is a diagram showing an aerial image display device 5 in the use state in accordance with an embodiment 2 of the present invention.

FIG. 9 is a diagram showing an aerial image display device 6 in the use state in accordance with the embodiment 3 of the present invention.

FIG. 10 is a side view showing the folded state of the aerial image display device 6 in accordance with the embodiment 3 of the present invention.

FIG. 11 is a front view showing the folded state of the aerial image display device 6 in accordance with the embodiment 3 of the present invention.

FIG. 12 is a back view showing the folded state of the aerial image display device 6 in accordance with the embodiment 3 of the present invention.

### BEST MODE FOR CARRYING OUT THE INVENTION

### Embodiment 1

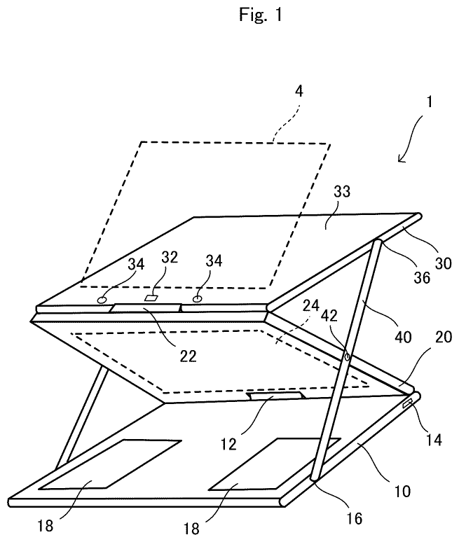

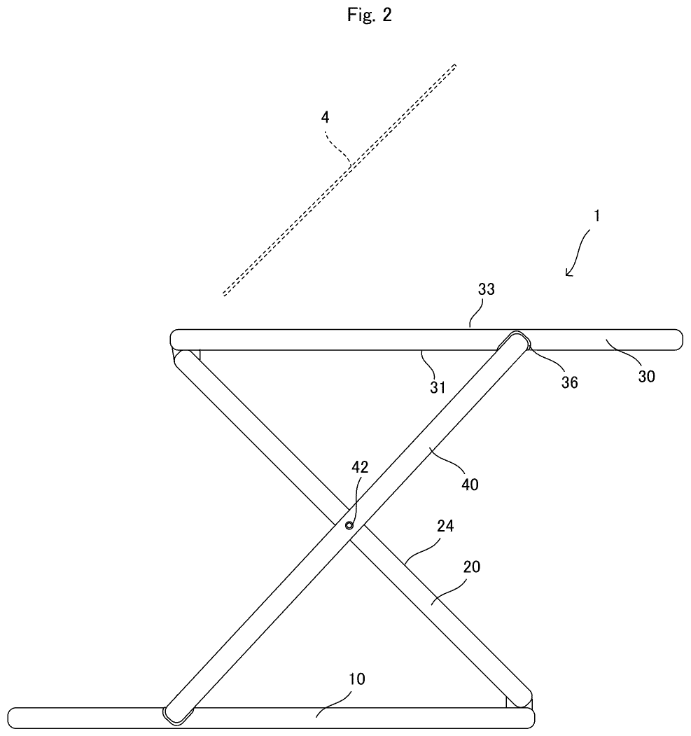

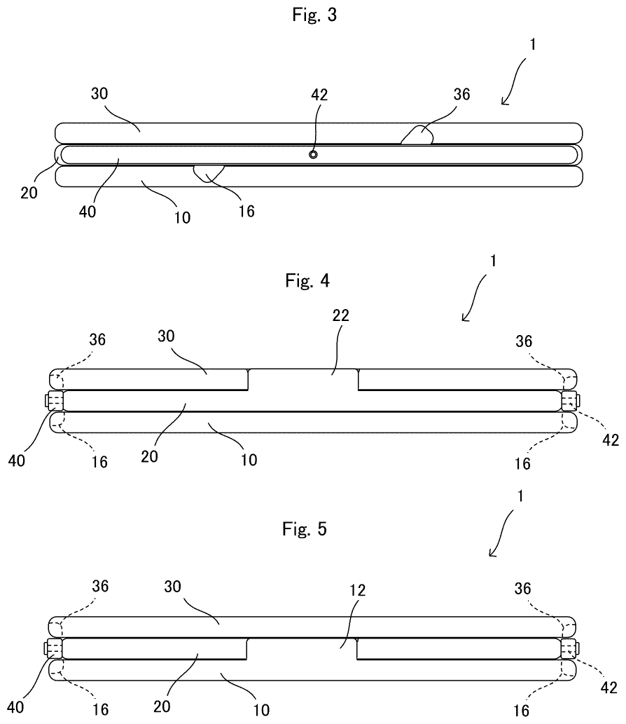

In what follows, a foldable aerial image display device in accordance with an embodiment 1 of the present invention will be explained with reference to the accompanying drawings. FIG. 1 is a perspective view showing an aerial image display device 1 in use according to the embodiment 1 of the present invention. FIG. 2 is a side view showing the aerial image display device 1 in use according to the embodiment 1 of the present invention. FIGS. 3, 4, and 5 are side, front, and back views of the folded aerial image display 1 shown in FIGS. 1 and 2.

As shown in these figures, the aerial image display device 1 includes a support substrate 10 in which an information processing apparatus for performing overall signal processing is installed, a liquid crystal display 20 connected to the support substrate 10 with a hinge member 12, and an optical plate 30 connected to this liquid crystal display 20 with a hinge member 22.

The information processing apparatus installed in the support substrate 10 is substantially a small computer, and includes a CPU (Central Processing Unit), a ROM (Read Only Memory), a RAM (Random Access Memory), and a storage device for storing various programs and data, an input/output interface, and so forth. As such input/output interfaces, for example, the USB port 14, a wireless equipment such as WIFI and the like are implemented.

The liquid crystal display 20 has a display surface 24 that faces the optical plate 30. That is, in the operational state of the aerial image display device 1 shown in FIGS. 1 and 2, the display surface 24 is inclined upward. Then, on the basis of the display data transmitted from the support substrate 10, a contactless interface, which will be described later, is displayed on the display surface 24.

The optical plate 30 has an incident surface 31 directed downward to face the display surface 24 of the liquid crystal display 20, and an output surface 33 directed upward. Then, the image on the display surface 24 of the liquid crystal display 20 is refocused as an aerial image 4 at the same distance on the opposite side of the optical plate 30, forming the same image as the original.

As such an optical plate 30, for example, an optical imaging element described in Japanese Unexamined Patent Application Publication No. 2011-175297 can be used. This optical imaging element can be implemented by arranging a large number of flat light reflectors orthogonal to each other at a constant pitch. In order to provide an optical imaging element, it is possible to make use of another structure such as a dihedral corner reflector in which reflecting surfaces are formed on the side surfaces of a rectangular hole as described in Japanese Patent No. 4900618.

An infrared LED 32 and a pair of infrared cameras 34 are provided on the optical plate 30 near the hinge member 22. The infrared LED 32 and the infrared camera 34 constitute an operation detection unit that detects an operation performed by the user on the aerial image 4. The detection range of the operation detection unit is defined by the emission angle of the infrared LED 32 and the angle of view of the infrared camera 34.

The support substrate 10, the liquid crystal display 20 and the optical plate 30 are connected by the hinge member 12 and the hinge member 22, respectively, and can be fixed by a pair of left and right locking rods 40 in the operational state of the aerial image display device 1 as shown in FIGS. 1 and 2.

That is, in each of left and right sides, the locking rod 40 is rotatably supported by a shaft 42 provided in the center of the side surface of the liquid crystal display 20, and can be engaged with an engagement recess 16 of the support substrate 10 and an engagement recess 36 of the optical plate 30. When both ends of the locking rod 40 are engaged with the engaging recesses 16 of the support substrate 10 and the engaging recesses 36 of the optical plate 30, the optical plate 30 is horizontally supported, and the liquid crystal display 20 is held at an angle of approximately 45 degrees downward from the optical plate 30. In this use state, the liquid crystal display 20 and the support substrate 10 are fixed at an angle of approximately 45 degrees.

It is important that the angle between the liquid crystal display 20 and the optical plate 30 and the angle between the liquid crystal display 20 and the support substrate 10 are both about 45 degrees. At this angle, the optical plate 30 is horizontal and the light from the liquid crystal display 20 is imaged into the aerial image 4 that is upright at about 45 degrees under optimum conditions. Specifically, the about 45 degrees should preferably be in the range of approximately 40 degrees to 50 degrees.

When an operation interface is displayed on the liquid crystal display 20 in this state, it is imaged on the opposite side of the optical plate 30 as a contactless interface 4. When a gesture such as touching the contactless interface 4 is performed with a finger, the operation is detected by the operation detection unit consisting of the infrared LED 32 and the infrared cameras 34, and a corresponding operation signal is sent to the information processing apparatus of the support substrate 10 for predetermined processing. Operation interfaces include, for example, controls such as buttons, checkboxes, and drop-down menus.

This aerial image display device 1 is advantageous in portability. That is, when carrying, both ends of the locking rod 40 are removed from the engaging recess 16 of the supporting substrate 10 and the engaging recess 36 of the optical plate 30, and the supporting substrate 10, the liquid crystal display 20 and the optical plate 30 are rotated around the hinge members 12 and 22 respectively, and folded horizontally into a small size as illustrated in the side view of FIG. 3, the front view of FIG. 4 and the back view of FIG. 5.

Therefore, the foldable aerial image display device according to the embodiment 1 of the present invention is a portable type that can be folded into a small size and freely carried. For example, it is possible to carry this aerial image display device in a bag and perform contactless online payment at the visiting place.

Meanwhile, as illustrated in FIG. 1, a speaker 18 may be provided on the support substrate 10. For example, when some operation is performed on the contactless interface 4 and it is detected, the user can be recognized this operation by a click sound or the like. Alternatively, a voice guidance may be reproduced for an unfamiliar user.

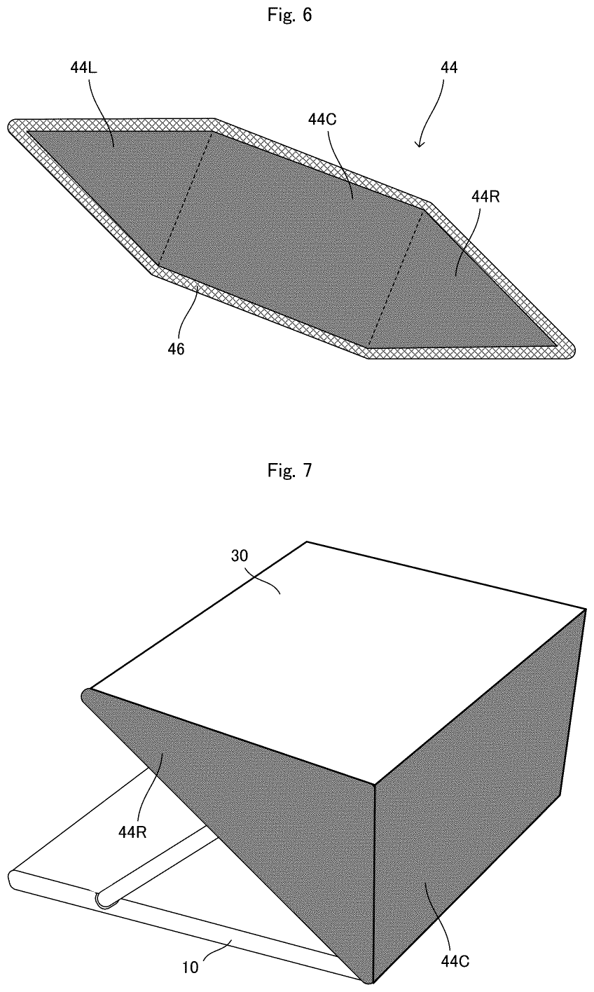

Moreover, in order to realize a clearer aerial image 4, it is desirable that external light is not mixed into the light from the liquid crystal display 20. For this purpose, a blackout curtain 44 shown in FIG. 6 can be used. This blackout curtain 44 is intended to cover the space between the liquid crystal display 20 and the optical plate 30, and consists of a left shielding part 44L, a central shielding part 44C, and a right shielding part 44R.

The left shielding part 44L covers the open area on the left side between the liquid crystal display 20 and the optical plate 30, the central shielding part 44C covers the open area in the center, that is, the back area between the liquid crystal display 20 and the optical plate 30, and the right shielding part 44R covers the open area on the right side between the liquid crystal display 20 and the optical plate 30.

A hook-and-loop fastener 46 is provided on the edges of the blackout curtain 44. Although not directly shown in the figure, the hook-and-loop fastener is also provided on the corresponding surface of the aerial image display device 1. The hook-and-loop fasteners on the blackout curtain 44 and the aerial image display device 1 are complementary (one side is the hook part, the other is the loop part), and as shown in FIG. 7, they can be attached to completely cover the space between the liquid crystal display 20 and the optical plate 30. As a result, no external light is added to the light from the liquid crystal display 20, allowing for a clearer aerial image 4.

It should be noted that although the blackout curtain 44 is intended to be attached during use, it can be permanently fixed to the liquid crystal display 20 and the optical plate 30 without being attached or removed. In this case, when folding the aerial image display device 1, it is folded between the liquid crystal display 20 and the optical plate 30. The folding method is, for example, a bellows fold, which folds in a zigzag manner like a folding fan.

### Embodiment 2

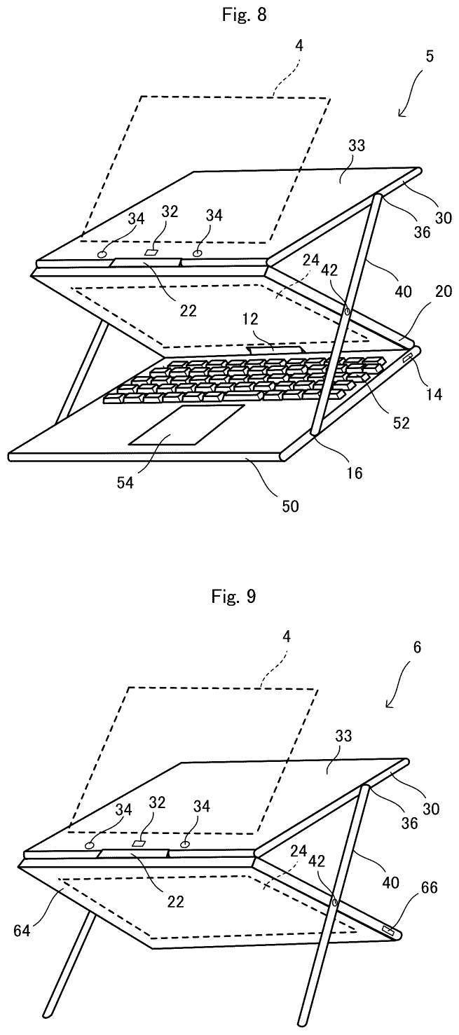

Next, an embodiment 2 of the aerial image display device according to the present invention will be explained. FIG. 8 is a perspective view showing the aerial image display device 5 in use according to the embodiment 2 of the present invention. The elements common to the aerial image display device 1 of the embodiment 1 of the present invention are assigned the same numbers, and their explanations are omitted.

Also, FIG. 2 is a side view showing the aerial image display device 1 in use according to the embodiment 1 of the present invention, and FIGS. 3, 4, and 5 are side views, front views, and back views, respectively, showing the folded state of the aerial image display device 1 according to the embodiment 1 of the present invention. These can also be seen as the side view of the aerial image display device in use according to the embodiment 2 of the present invention, and the side view, front view, and back view of the aerial image display device 5 showing the folded state of the aerial image display device according to the embodiment 2 of the present invention. However, the supporting board 10 is replaced with the body 50 of a notebook computer.

That is, the aerial image display device 5 according to the embodiment 2 of the present invention replaces the supporting board 10 of the aerial image display device 1 according to the embodiment 1 of the present invention with the body 50 of the notebook computer. The body 50 of the notebook computer includes elements typically found in notebook computers, such as a keyboard 52 and a touchpad 54, and this aerial image display device 5 can be used as a notebook computer with the aerial image 4 as its monitor.

Also, as in the embodiment 1, since it can be folded into a small size and is easy to carry, a contactless interface can be easily installed at any place. Particularly, with the convenience of a notebook computer, the non-contact interface of the aerial image display device 5 can efficiently developed, maintained and modified on site. It should be noted that, as in the embodiment 1, it is desirable to use the blackout curtain 44 shown in FIG. 6 to achieve a clearer aerial image 4.

### Embodiment 3

Next, an embodiment 3 of the aerial image display device according to the present invention will be explained. FIG. 9 is a perspective view showing an aerial image display device 6 in use according to the embodiment 3 of the present invention. The elements common to the aerial image display device 1 of the embodiment 1 of the present invention are assigned the same numbers, and their explanations are omitted.

The aerial image display device of the embodiment 3 omits the supporting board 10 from the aerial image display device 1 of the embodiment 1. Therefore, this aerial image display device 6 is supported in use by a liquid crystal display 64 and a pair of locking rods 40 on the left and right. In the state of use shown in FIG. 9, the optical plate 30 is supported horizontally, and the liquid crystal display 64 is fixed at a 45-degree angle downward relative to the optical plate 30.

The liquid crystal display 64 is simply an external display device, equipped with a video input terminal 66 such as HDMI (registered trademark) and DISPLAY PORT. By connecting the video output terminal of a typical notebook computer to the video input terminal 66 of the liquid crystal display 64, the liquid crystal display 64 becomes an external display for the notebook computer.

In this case, since the aerial image display device can be realized simply by connecting the existing liquid crystal display and the optical plate with a hinge, it is possible to develop the system at a very low cost. Additionally, since a real machine development environment can be realized simply by connecting it to a notebook computer via an HDMI (registered trademark) terminal, the development period can be significantly shortened.

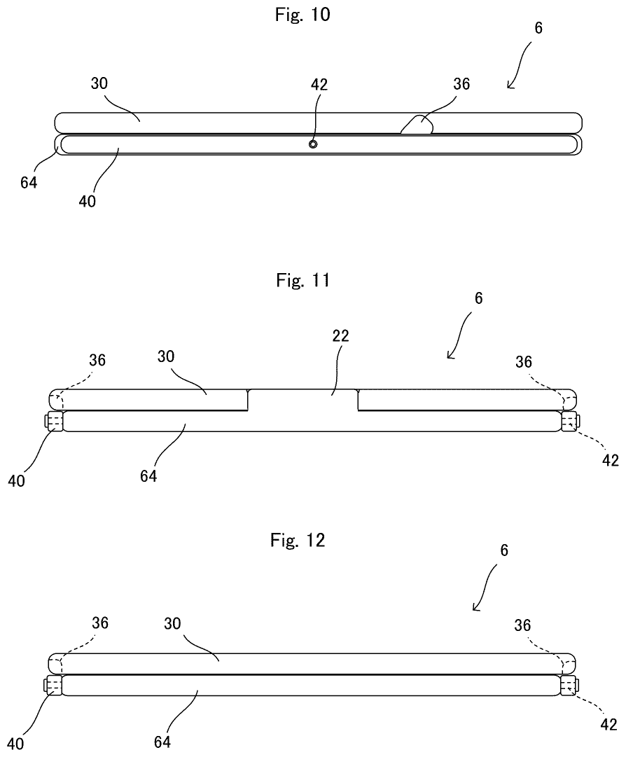

Therefore, the foldable aerial image display device 6 according to the embodiment 3 of the present invention is also a portable type that can be folded into a small size so that the liquid crystal display 64 and the optical plate 30 are stacked, and can be carried freely. FIGS. 10, 11, and 12 are side, front, and back views showing the folded state of the aerial image display device 6 according to the embodiment 3 of the present invention. For example, this aerial image display device can be folded, put into a bag, and carried around to perform non-contact online payments when visiting a destination.

It is also desirable here, as in the embodiment 1, to install the blackout curtain 44 shown in FIG. 6 between the liquid crystal display 64 and the optical plate 30 to achieve a clearer aerial image 4.

### INDUSTRIAL APPLICABILITY

According to the aerial image display device related to the present invention, it can be folded into a small size and carried freely. In addition, since the development environment using the actual machine can be set up on the spot, it is possible to easily modify and add the implementation.

The foregoing description of the embodiments has been presented for purposes of illustration and description. It is not intended to be exhaustive or to limit the invention to the precise form described, and obviously many modifications and variations are possible in light of the above teaching. The embodiment was chosen in order to explain most clearly the principles of the invention and its practical application thereby to enable others in the art to utilize most effectively the invention in various embodiments and with various modifications as are suited to the particular use contemplated.

For example, although a liquid crystal display is adopted in the above embodiments, the present invention is not limited to this, and organic EL displays or electronic paper, etc., may also be used. Also, although locking rods are used as the support structure to fix the display and the optical plate, the present invention is not limited to this. For example, a locking mechanism can be implemented in the hinge itself, or a shielding plate may be used instead of the blackout curtain, and this shielding plate can be utilized also as the support structure to fix the display and the optical plate.

### EXPLANATION OF SYMBOLS

1, 5 and 6 aerial image display device
4 aerial image
10 support structure
12 hinge member
14 USB port
16 engagement recess
18 speaker
20 liquid crystal display device
22 hinge member
24 display surface
30 optical plate
31 incident surface
32 infrared LED
33 output surface
34 infrared camera
36 engagement recess
40 locking rod
42 shaft
44 blackout curtain
44C central shielding part
44L left shielding part
44R right shielding part
46 hook-and-loop fastener
50 notebook computer body
52 keyboard
54 touchpad
64 liquid crystal display
66 video input terminal

1-5. (canceled)

6. A foldable aerial image display device, comprising:
a display substrate for displaying a contactless interface;
an optical plate pivotally connected to the front edge of the display substrate by a hinge;
an operation detection unit installed on the optical plate to detect gestures performed by a user;
a support substrate pivotally connected to the edge of the display substrate opposite the front edge; and
and a locking member to fix the display substrate and the optical plate at a certain angle, and fix the display substrate and the support substrate at a certain angle,
wherein when the contactless interface is displayed on the display substrate with the display substrate and the optical plate being fixed at the certain angle, the contactless interface is projected through the optical plate as an aerial image on the opposite side of the optical plate, and
wherein the display substrate, the optical plate, and the support substrate can be folded flat by rotating them around the hinges.

7. The foldable aerial image display device according to claim 6, wherein
the support substrate incorporates an information processing device that transmits control signals to the display substrate to display the contactless interface.

8. The foldable aerial image display device according to claim 7, wherein
the locking member maintains the optical plate and the support substrate horizontally and allows the angle between the optical plate and the display substrate and the angle between the support substrate and the display substrate to be fixed in the range of 40 to 50 degrees.
